(19) United States
(12) Patent Application Publication
(10) Pub. No.: US 2007/0090533 A1
(43) Pub. Date: Apr. 26, 2007

(54) Closed loop thermally enhanced flip chip BGA

(75) Inventors: Chris Haga, McKinney, TX (US); Anthony Louis Coyle, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/257,252

(22) Filed: Oct. 24, 2005

(51) Int. Cl. H01L 23/52

(52) U.S. Cl. 257/777

(57) ABSTRACT

According to one or more aspects of the present invention, a flip chip BGA packaging or mounting arrangement is disclosed where a grounding connection of implemented on the back of the chip. The grounding connection comprises one or more metal strips that are situated between the back of the chip and a printed circuit board upon which the chip is operatively coupled via BGA, or between that back of the chip and a heat spreader that is itself operatively coupled to the printed circuit board. The backside grounding connection enhances stability in switching applications, for example, particularly where the chip includes silicon on insulator (SOI) wafer processing.

### FIELD OF INVENTION

The present invention relates generally to semiconductor technologies and more particularly to an arrangement that facilitates electrical contact to the backside of a flip chip.

### BACKGROUND OF THE INVENTION

Integrated circuits or semiconductor chips are formed on semiconductor wafers, and more particularly on die on the wafers. The die or chips are then cut or otherwise separated from the wafers, and the individual chips are then handled and packaged. The packaging process is one of the most critical steps in the integrated circuit fabrication process, both from the point of view of cost and of reliability. Specifically, the packaging cost can easily exceed the cost of the integrated circuit chip and many device failures can be attributed to packaging processes.

The integrated circuit must be packaged in a suitable media that will protect it in subsequent manufacturing steps and from the environment of its intended application. Wire bonding and encapsulation are two main steps in the packaging process. Wire bonding connects the leads from the chip to the terminals of the package. The terminals allow the integrated circuit package to be connected to other components. Following wire bonding, encapsulation is employed to seal the surfaces from moisture and contamination and to protect the wire bonding and other components from corrosion and mechanical shock.

Conventionally, the packaging of integrated circuits has involved attaching an individual chip to a lead frame, where, following wire bonding and encapsulation, designated parts of the lead frame become the terminals of the package. The packaging of integrated circuits has also involved the placement of chips on a flexible board where, following adhesion of the chip to the surface of the flexible board and wire bonding, an encapsulant is placed over the chip and the adjacent flexible board to seal and protect the chip and other components.

Unfortunately, current methods for encapsulating silicon chips have led to various problems, including cracking between the encapsulation material and the integrated circuit components, as well as high failure rates due to the multi-step nature of the process. Cracking has plagued the industry because of differences in the coefficient of thermal expansion of the different components, for example, between the soldering materials at the different interfaces and between metallic and non-metallic components. Cracking is also frequent between the silicon wafer and the encapsulation materials, usually epoxies, due to the extreme variations in temperature in various environments and between periods of operation and non-operation.

Even if the encapsulated silicon chip is successfully assembled into a working integrated circuit, another problem is commonly encountered. Once the silicon chip is encapsulated it is typically surface mounted using radiant heat or vapor saturated heating. This process, however, can lead to poor coplanarity due to uneven reflow, leading to integrated circuit failure.

Ball Grid Array (BGA) packages have emerged as an excellent packaging solution for integrated circuit (IC) chips with high input/output (I/O) count. BGA packages use solder balls for surface mount connection to the “outside world” (typically plastic circuit boards (PCB)) rather sensitive package leads, as in Quad Flat Packs (QFP), Small Outline Packages (SOP), or Tape Carrier Packages (TCP). Some BGA advantages include ease of assembly, use of surface mount process, low failure rate in PCB attach, economic use of board area, and robustness under environmental stress. The latter used to be true only for ceramic BGA packages, but has been validated in the last few years even for plastic BGAs. From the standpoint of high quality and reliability in PCB attach, BGA packages lend themselves much more readily to a six-sigma failure rate fabrication strategy than conventional devices with leads that have to be soldered.

Fiip chip assembly is used in BGA packaging, where the integrated circuit is “flipped” or mounted upside. Accordingly, flip chip assembly involves the face-down connection of electronic components onto substrates or printed circuit boards by means of conductive bumps on the chip bond pads. By contrast, wire bonding uses face-up chips with a wire connection to each pad. There are three primary stages in making flip chip assemblies: bumping the die or wafer, attaching the bumped die to the board or substrate, and, in most cases, filling the remaining space under the die with an electrically non-conductive material. The bump serves several functions in the flip chip assembly. Electrically, the bump provides the conductive path from chip to substrate or PCB. The bump also provides a thermally conductive path to carry heat from the chip to the substrate. In addition, the bump, provides part of the mechanical mounting of the die to the substrate. Finally, the bump provides a space, preventing electrical contact between the chip and substrate. In the final stage of assembly, this space is usually filled with a non-conductive “underfill” adhesive joining the entire surface of the chip to the substrate. The underfill protects the bumps from moisture or other environmental hazards, provides additional mechanical strength to the assembly, and compensates for any thermal expansion difference between the chip and the substrate. Underfill mechanically “locks together” chip and substrate so that differences in thermal expansion are less likely to break or damage the electrical connection of the bumps.

A Ball Grid Array (BGA) package is primarily composed of three basic parts: the bare chip, a BGA substrate, and an interconnection matrix. The flip-chip is connected to the BGA substrate face-down, while the interconnection matrix connects the bare chip to the BGA substrate using direct attach flip-chip style connections. The BGA substrate, which includes very small traces and vias, conveys signals to the underlying printed circuit board through the solder-bump attachment pads on its bottom surface. A metal cover or plastic encapsulation is then used to seal the package.

Nevertheless, despite the advantages associated with flip chip BGA packaging arrangements, some chips may not operate as desired. For example, where silicon on insulator (SOI) processing is incorporated into the chips and the chips are utilized in applications where stability during operation at frequency is critical (e.g., during switching applications), the chips may lack stability.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its purpose is merely to present one or more concepts of the invention in a simplified form as a prelude to the more detailed description that is presented later.

According to one or more aspects of the present invention, a flip chip BGA packaging or mounting arrangement is disclosed where a grounding connection is implemented on the back of the chip. The grounding connection comprises one or more metal strips that are situated between the back of the chip and a printed circuit board upon which the chip is operatively coupled via BGA, or between that back of the chip and a heat spreader that is itself operatively coupled to the printed circuit board. The backside grounding connection enhances stability in applications where stability during operations at frequency is critical (e.g., during switching operations), particularly where the chip includes silicon on insulator (SOI) wafer processing.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1 is a cross sectional view illustrating an exemplary flip chip BGA arrangement according to one or more aspects of the present invention.

FIG. 2 is another cross sectional view illustrating an exemplary flip chip BGA arrangement according to one or more aspects of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, that one or more aspects of the present invention may be practiced with a lesser degree of these specific details. In other instances, structures and devices are shown in block diagram form in order to facilitate describing one or more aspects of the present invention.

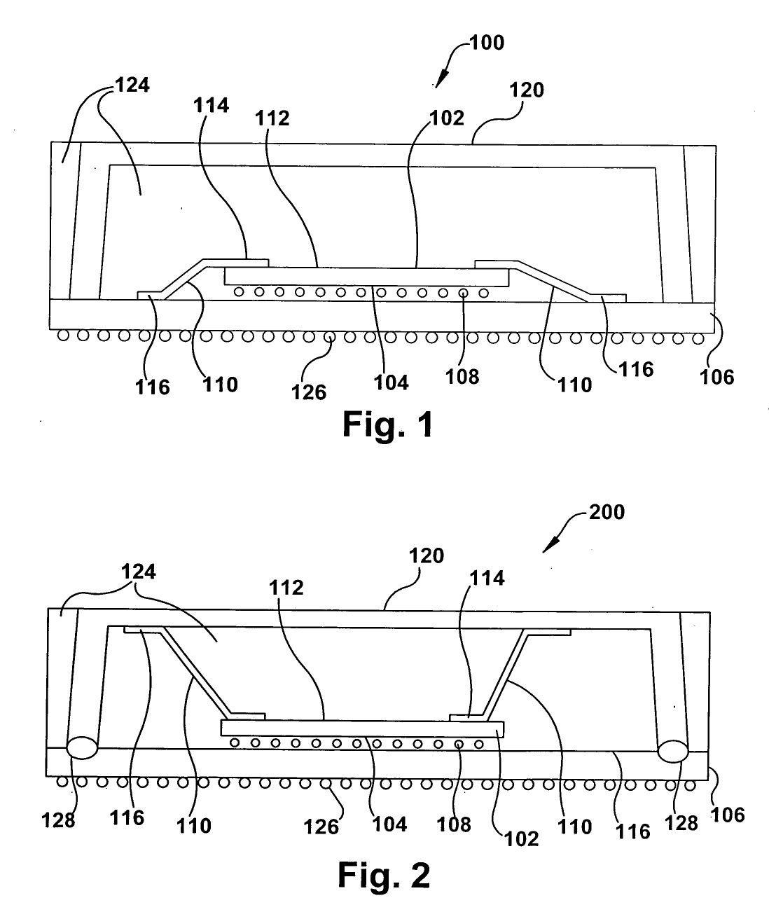

One or more aspects of the present invention pertain to a flip chip ball grid array (BGA) mounting or packaging arrangement where a backside grounding connection is implemented to promote stability, particularly where the chip is used in applications where stability during operation at frequency is critical and includes SOI wafer processing. Turning to FIG. 1, an exemplary flip chip BGA arrangement 100 is illustrated according to one or more aspects of the present invention. The arrangement 100 includes an integrated circuit (IC) chip 102 which may correspond to a die of a semiconductor wafer for example. The chip 102 is “flipped” so that a face 104 of the chip 102 faces a printed circuit board (PCB) or substrate 106 onto which the chip is operatively coupled via a plurality of solder balls or bumps 108.

It will be appreciated that the chip 102 generally comprises one or more microelectronic devices, such as transistors, electrically programmable read only memory (EPROM) cells, electrically,erasable programmable read only memory (EEPROM) cells, static random access memory (SRAM) cells, dynamic random access memory (DRAM) cells and other microelectronic devices, which may be interconnected to form one or more integrated circuits. Electrically conductive lines known as interconnects are also included in the chip 102 to electrically connect the microelectronic devices to corresponding electrically conductive balls 108. It will also be appreciated that the balls 108 are generally arranged in an array and may be formed out of solder or any other electrically conductive material. Additionally, the balls 108 have a substantially spherical shape, at least before being reflowed, such as by a heating process, for example.

In addition, while the substrate 106 is generally referred to as a printed circuit board herein, it is to be appreciated that the substrate 106 may include a multiple chip package substrate and/or other type(s) of substrate. Further, the bulk of the chip 102 and/or the PCB substrate 106 may comprise silicon-on-insulator (SOI), silicon, gallium arsenide, strained silicon, silicon germanium, carbide, diamond and/or other materials.

According to one or more aspects of the present invention, an electrically conductive strip 110 is attached to the backside 112 of the flipped chip 102 to facilitate a grounding connection. While two strips 110 are depicted in the illustrated example, it is to be appreciated that any suitable number of strips can be included to achieve the desired level of grounding. Respective first ends 114 of the strips 110 are operatively coupled to the backside 112 of the chip 102 while respective second ends 116 of the strips 110 are operatively coupled to the PCB substrate 106.

The strips 110 provide stable contact to ground or to some other very negative potential on the substrate 106. Since the chip 102 is flipped, it will be appreciated that the strips 110 are attached to the substrate of the chip 102, which may or may not be doped. The strips 110 can comprise any type of electrically conductive material, such as any type of metal (e.g., gold, aluminum, copper, etc.). Additionally, the first 114 and second 116 ends of the strips 110 can be coupled to the backside 112 of the chip 102 and to the substrate 106, respectively, in any suitable manner, such as with solder and/or electrically conductive epoxy, for example.

It can be appreciated that during operation, the chip 102 may generate heat and that if the heat rises above a certain threshold, the speed, performance, and lifetime of the chip and/or microelectronic devices formed therein may be adversely affected. Accordingly, a heat spreader 120 is included which diffuses heat and thus mitigates over heating of the chip 102. The heat spreader 120 may comprise one or more layers of a solid and/or rigid thermally conductive material. For example, the heat spreader 120 can have a thermal conductivity ranging between about 140 W/m degree K and about 500 W/m degree K. For example, copper may be employed in the heat spreader because it has a thermal conductivity of about 400 W/m degree K. The heat spreader may also comprise silver, gold and/or aluminum, for example. The heat spreader may have a thickness ranging from between about 500 Angstroms and about 5000 Angstroms, for example.

The heat spreader 120 is generally formed within close proximity to the chip 102 to facilitate efficient heat transfer from the chip 102. It will be appreciated that a heat sink (not shown) may be operatively coupled to the heat spreader 120 to absorb heat therefrom. It can also be appreciated that situating heat spreader 120 over the chip 102 as illustrated also adds a protective cover over the chip 102 where, for example, the chip 102 and ball grid array 108 may be sensitive to stresses applied thereto. Mold compound 124 is also formed under and around the chip 102 and heat spreader 120 to further protect and insulate the chip 102 from external noise and debris.

A plurality of electrically conductive balls 126 are illustrated under the PCB substrate 106. Like balls 108, balls 106 can comprise any suitable electrically conductive material and may be reflowed by adding heat, for example, to facilitate electrical connections. The balls 108 are thus routed through the PCB substrate 106 to the balls 126 below the substrate 106 based upon some design criteria.

FIG. 2 illustrates another exemplary flip chip BGA arrangement 200 according to one or more aspects of the present invention. Similar components are identified with similar reference characters and thus are not discussed again for purposes of brevity. In the example of FIG. 2, second ends 116 of the strips 110 are attached to the heat spreader 120 to facilitate the grounding connection, where the heat spreader 120 is coupled to the substrate 106. In the illustrated example, the heat spreader 120 is coupled to the substrate 106 via a conductive material 128, such as solder and/or a conductive epoxy, for example. It will be appreciated that the strips 110 can similarly be attached to the head spreader 120 with any suitable conductive material 128, such as solder and/or a conductive epoxy, for example.

Additionally, the strips 110 can be attached to the heat spreader 120 before the heat spreader 120 is situated over the chip 102 and attached to the substrate 106. The strips 110 and heat spreader 120 would thus be set over the chip 102 as a unit. The molding compound can then be injection molded around the chip 102 and strips 110. Alternatively, the strips 110 could be attached to the chip 102 first and then the compound 124 could be overmolded around the chip and the strips and then the heat spreader 120 could be applied (followed by the addition of more molding compound). The same is true for the example of FIG. 1, where the mold compound 124 can be added before or after the strips 110 are affixed and/or before or after the heat spreader 120 is situated over the chip 102. Likewise, the strips 110 in FIGS. 1 and 2 can be affixed before or after the balls 108 and/or 126 are reflowed.

Finally, it will be appreciated that while the disclosure herein has been discussed in the context of SOI, that one or more aspects of the present invention are not limited thereto, but instead have application to any type integrated circuitry.

Although the invention has been shown and described with respect to one or more implementations, equivalent alterations and/or modifications may be evident based upon a reading and understanding of this specification and the annexed drawings. The invention includes all such modifications and alterations and is limited only by the scope of the following claims. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” as utilized herein merely means an example, rather than the best.

What is claimed is:

1. A flip chip BGA arrangement, comprising:
an integrated circuit chip;
a printed circuit board;
an plurality of electrically conductive balls that operatively couple a face of the chip that faces the circuit board to the circuit board, the balls being substantially spherical shape, at least until being reflowed; and
an electrically conductive strip operatively coupled to a backside of the chip to facilitate a grounding connection.

2. The arrangement of claim 1, where a first end of the electrically conductive strip is operatively coupled to the backside of the chip and a second end of the electrically conductive strip is operatively coupled to the printed circuit board.

3. The arrangement of claim 2, where the chip has SOI wafer processing and is utilized in an application where stability during operation at frequency is critical.

4. The arrangement of claim 2, where the strip comprises at least one of gold, aluminum and copper.

5. The arrangement of claim 3, where the strip comprises at least one of gold, aluminum and copper.

6. The arrangement of claim 2, where the first end of the electrically conductive strip is coupled to the backside of the chip by at least one of solder and an electrically conductive epoxy.

7. The arrangement of claim 2, further comprising:
mold compound surrounding the flip chip.

8. The arrangement of claim 2, further comprising:
a heat spreader operatively coupled to the printed circuit board and situated around the flip chip to transfer heat away from the chip.

9. The arrangement of claim 8, where the second end of the strip is coupled to the printed circuit board by being coupled to the heat spreader.

10. The arrangement of claim 9, where the chip has SOI wafer processing and is utilized in an application where stability during operation at frequency is critical.

11. The arrangement of claim 9, where the strip comprises at least one of gold, aluminum and copper.

12. The arrangement of claim 10, where the strip comprises at least one of gold, aluminum and copper.

13. The arrangement of claim 9, where at least one of
the first end of the electrically conductive strip is coupled to the backside of the chip by at least one of solder and an electrically conductive epoxy, and
the second end of the strip is coupled to the heat spreader by at least one of solder and an electrically conductive epoxy.

14. The arrangement of claim 9, where the heat spreader is operatively coupled to the printed circuit board by at least one of solder and an electrically conductive epoxy.

15. The arrangement of claim 4, further comprising:
mold compound surrounding the flip chip and situated between the heat spreader and the flip chip.

16. A flip chip BGA arrangement, comprising:
an integrated circuit chip having SOI wafer processing and utilized in an application where stability during operation at frequency is critical;
a printed circuit board;
an plurality of electrically conductive balls that operatively couple a face of the chip that faces the circuit board to the circuit board, the balls being substantially spherical shape, at least until being reflowed;
a heat spreader operatively coupled to the printed circuit board by at least one of solder and an electrically conductive epoxy and situated around the flip chip to transfer heat away from the chip;
mold compound surrounding the flip chip and situated between the heat spreader and the flip chip; and
an electrically conductive strip comprising at least one of gold, aluminum and copper and configured to facilitate a grounding connection, where
a first end of the strip is operatively coupled to a backside of the chip by at least one of solder and an electrically conductive epoxy, and
a second end of the strip is operatively coupled to the printed circuit board.

17. The arrangement of claim 16, where the second end of the strip is operatively coupled to the printed circuit board by being coupled to the heat spreader.

18. A method of stabilizing a flip chip BGA arrangement, comprising:
operatively associating an electrically conductive strip to a backside of the flip chip to facilitate a grounding connection.

19. The method of claim 18, further comprising:
connecting a first end of the strip to the backside of the chip and a second end of the strip to a printed circuit board upon which the chip is operatively situated.

20. The method of claim 19, further comprising:
connecting the second end of the strip to the printed circuit board by connecting the second end of the strip to a heat spreader that is itself operatively coupled to the printed circuit board.
